(19) United States
(12) Patent Application Publication
(10) Pub. No.: US 2010/0036629 A1
(43) Pub. Date: Feb. 11, 2010

(54) Method and Device for Recognizing Pulses

(75) Inventor: Sven Semmelrodt, Bosingen (DE)

Correspondence Address: King & Spalding LLP, 401 Congress Avenue, Suite 3200, Austin, TX, 78701, US

(73) Assignee: Continental Automotive GmbH, Hannover (DE)

(21) Appl. No.: 12/296,028

(22) PCT Filed: Jan. 15, 2008
(86) PCT No.: PCT/EP2008/050397

§ 371 Date: Oct. 16, 2009

(30) Foreign Application Priority Data
Feb. 1, 2007 (DE) 10 2007 005 890.1

(51) Int. Cl. G06F 19/00; G01R 29/00

(52) U.S. Cl. 702/66

(57) ABSTRACT

A series (FA) of scanning values (AW) is transformed into a series (FT) of transformation values (TW) by adding one respective transformation value (TW) representing a current scanning value (AW) of the series (FA) of scanning values (AW) to the series (FT) of transformation values (TW) if the current scanning value (AW) of the series (FA) of scanning values (AW) deviates from a given reference scanning value (REF) at least by a given net value (MDIFF). The current scanning value (AW) of the series (FA) of scanning values (AW) which deviates from the given reference scanning value (REF) at least by the given net value (MDIFF) is predefined as the given reference scanning value (REF) for subsequent current scanning values (AW). A moving average (M) is determined in accordance with the series (FT) of transformation values (TW). Pulses (IMP) are recognized in accordance with the moving average (M).

### CROSS-REFERENCE TO RELATED APPLICATIONS

This application is a U.S. National Stage Application of International Application No. PCT/EP2008/050397 filed Jan. 15, 2008, which designates the United States of America, and claims priority to German Application No. 10 2007 005 890.1 filed Feb. 1, 2007, the contents of which are hereby incorporated by reference in their entirety.

### TECHNICAL FIELD

The invention relates to a method and to a device for recognizing pulses and, in particular, for recognizing pulses which are generated by a pulse generator wheel and a sensor, which comprises a Hall element for example, for determining a rotation speed, in particular in a transmission of a vehicle.

### BACKGROUND

EP 1 111 392 A1 discloses detecting a rotation speed and angular position of a rotating wheel with an adjustable switching threshold for drift compensation. A sensor samples the sample marks of the wheel in a contact-free manner and generates a pulse sequence. An amplitude of the pulses is compared in a comparator with a variable switching threshold by an evaluation circuit with a synchronous detector and filter. In order to achieve the most accurate measurement result possible and to largely compensate for an offset and a long-term drift of the sensor, the switching threshold is adjusted when one or more conditions is/are satisfied.

DE 699 10 741 T2 discloses a circuit for establishing a change in a magnetic field. A difference signal is generated from an output signal from magnetic field sensors. A peak value of the difference signal is recognized and tracked. A threshold value adjusting circuit is provided in order to set a threshold value in accordance with the magnitude of the difference signal.

### SUMMARY

A reliable method and a device for recognizing pulses can be provided.

According to an embodiment, a method for recognizing pulses in an input signal, may comprise the steps: transforming a sequence of sample values, which is formed as a function of the input signal or which is formed by the input signal, into a sequence of transformation values by in each case adding a transformation value, which represents a current sample value of the sequence of sample values, to the sequence of transformation values when this current sample value of the sequence of sample values deviates from a predefined reference sample value at least by a predefined magnitude value, predefine the current sample value of the sequence of sample values, which deviates from the predefined reference sample value at least by the predefined magnitude value, as the predefined reference sample value for subsequent current sample values, determining a sliding average value as a function of the sequence of transformation values, and recognizing pulses in the input signal as a function of the sliding average value.

According to an embodiment, the current sample value of the sequence of sample values, which deviates from the predefined reference sample value at least by the predefined magnitude value, can be added as the transformation value to the sequence of transformation values. According to an embodiment, an amplitude of at least one pulse can be determined, and the predefined magnitude value can be predefined as a function of the determined amplitude of the at least one pulse and a predefined number of amplitude sections into which the determined amplitude of the at least one pulse is to be divided. According to an embodiment, the input signal or a signal which is derived from this input signal can be supplied to a threshold value switching unit, and the sliding average value is predefined to the threshold value switching unit as a threshold value or a threshold value which is determined as a function of the sliding average value.

According to a further embodiment, a device for recognizing pulses in an input signal, the device being operable—to transform a sequence of sample values, which is formed as a function of the input signal or which is formed by the input signal, into a sequence of transformation values by in each case adding a transformation value, which represents a current sample value of the sequence of sample values, to the sequence of transformation values when this current sample value of the sequence of sample values deviates from a predefined reference sample value at least by a predefined magnitude value, —to predefine the current sample value of the sequence of sample values, which deviates from the predefined reference sample value at least by the predefined magnitude value, as the predefined reference sample value for subsequent current sample values, —to determine a sliding average value as a function of the sequence of transformation values, and—to recognize pulses in the input signal as a function of the sliding average value.

### BRIEF DESCRIPTION OF THE DRAWINGS

Exemplary embodiments of the invention are explained below with reference to the schematic drawings, in which:

FIG. 1 shows a device for recognizing pulses,

FIG. 2 shows a graph with a first time profile of a sequence of sample values,

FIG. 3A shows a graph with a second time profile of the sequence of sample values,

FIG. 3B shows a graph with a time profile of a sequence of transformation values, and

FIG. 4 shows a flowchart of a program for recognizing pulses.

Elements which have the same structure or function are provided with the same reference symbols in all of the figures.

### DETAILED DESCRIPTION

According to various embodiment, in a method and a corresponding device for recognizing pulses in an input signal, a sequence of sample values, which is formed as a function of the input signal or which is formed by the input signal, is transformed into a sequence of transformation values by in each case adding a transformation value (TW), which represents a current sample value of the sequence of sample values, to the sequence of transformation values when this current sample value of the sequence of sample values deviates from a predefined reference sample value at least by a predefined magnitude value. The current sample value of the sequence of sample values, which deviates from the predefined reference sample value at least by the predefined magnitude value, is predefined as the predefined reference sample value for subsequent current sample values. A sliding average value is determined as a function of the sequence of transformation values. Pulses in the input signal are recognized as a function of the sliding average value.

For example, a threshold value for recognizing the pulses is predefined as a function of the sliding average value, in particular, the sliding average value can also form the threshold value directly. One advantage is that the transformation can effect decimation of the sequence of sample values. As a result, only a few transformation values have to be stored and taken into account compared to a number of sample values for the purpose of further processing. As a result, the device can be designed in a very simple and cost-effective manner. In particular, the device can thus be implemented in a simple and cost-effective manner in an application-specific integrated circuit, which can also be called an ASIC. However, the method can also be implemented as a program which can be executed, for example, on a microcontroller.

A further advantage is that an amplitude offset, which changes slowly in comparison to a frequency of the pulses and can also be called an offset or drift, can be compensated for in a simple and reliable manner. This applies, in particular, when the input signal is noisy and/or the amplitude offset is greater than an amplitude of the pulses. Furthermore, compensation is also possible in a reliable manner when a frequency dynamic of the pulses is large, for example when a frequency of the pulses can vary between approximately 1 Hz and 10 kHz. The method and the device are particularly suitable for recognizing pulses which are used for determining a rotation speed in a transmission of a vehicle and which are detected by using a static sensor principle by way of a permanent magnet and a Hall element as the sensor. The amplitude offset is caused, for example, by an eddy current brake.

According to an embodiment, the current sample value of the sequence of sample values, which deviates from the predefined reference sample value at least by the predefined magnitude value, is added as the transformation value to the sequence of transformation values. The advantage is that this is particularly simple.

In a further embodiment, an amplitude of at least one pulse is determined. The predefined magnitude value is predefined as a function of the determined amplitude of the at least one pulse and a predefined number of amplitude sections into which the determined amplitude of the at least one pulse is to be divided. This has the advantage that the predefined magnitude value can be automatically adjusted very easily. Manual adjustment is then not necessary. As a result, costs can be saved.

In a further embodiment, the input signal or a signal which is derived from this input signal is supplied to a threshold value switching unit. Furthermore, the sliding average value, as the threshold value, or a threshold value which is determined as a function of the sliding average value is predefined to the threshold value switching unit. The threshold value switching unit is preferably designed as a digital comparator which compares the respective digitally encoded sample value with the respective digitally encoded threshold value. The advantage is that this can be implemented in a very simple and cost-effective manner.

A sensor unit SENS is provided for detecting a signal (FIG. 1). The sensor unit SENS comprises, for example, a Hall element and is designed to generate the signal as a function of a prevailing magnetic field. For example, the magnetic field is generated by a permanent magnet which is arranged in a generator wheel which is fixed to a rotating component, for example a shaft. Rotation of the generator wheel produces pulses IMP in the signal whose frequency is dependent on a rotational speed of the generator wheel. The sensor unit SENS and the generator wheel are arranged, for example, in a transmission. A rotation speed of the generator wheel and therefore of the rotating component can be determined as a function of the pulses IMP.

The sensor unit SENS is coupled to a signal processing unit SIG to which the detected signal can be supplied. The signal processing unit SIG is preferably designed to preprocess in an analog fashion, for example to amplify and to filter, the signal. The signal processing unit SIG is coupled to an analog/digital converter unit ADW to which the preprocessed signal can be supplied. The analog/digital converter unit ADW is designed to digitize, that is to say to sample, the detected and preprocessed signal. A filter unit, and particularly a low-pass filter unit TP, is preferably provided to filter, and particularly to low-pass-filter, the digitized signal.

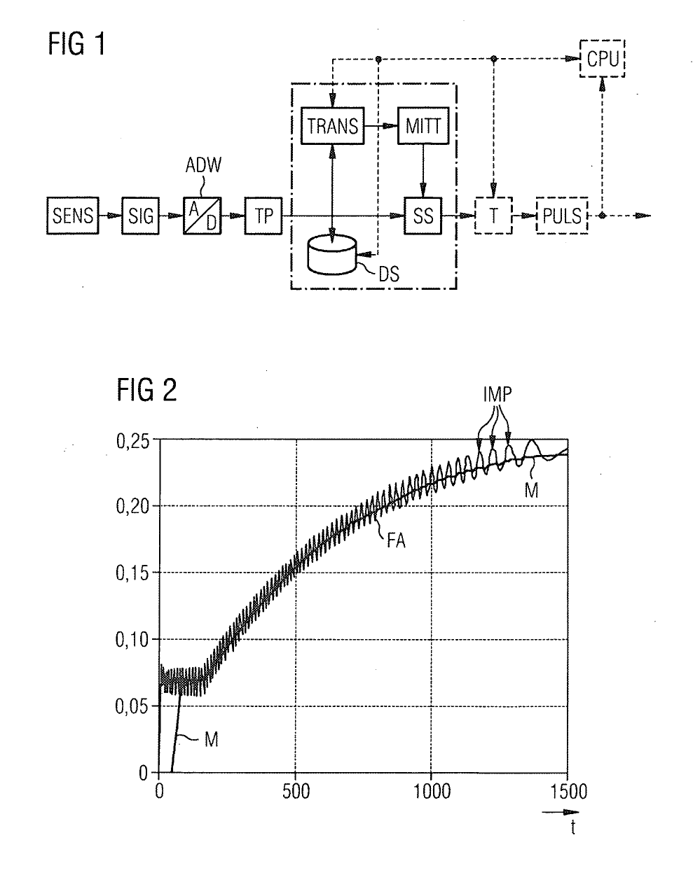

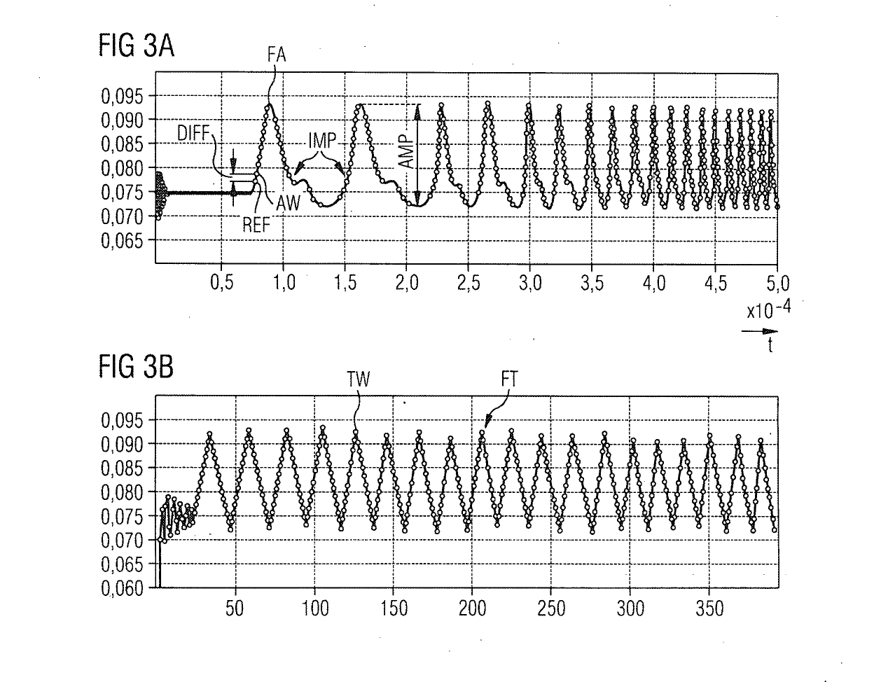

The signal, which is digitized by the analog/digital converter unit ADW and possibly filtered by the filter unit, forms a sequence FA of sample values AW which is supplied to a device for recognizing pulses IMP as an input signal. A first and a second profile of the sequence FA of sample values AW are illustrated by way of example in FIGS. 2 and 3A. The device is coupled at the input end to the filter unit and comprises a transformation unit TRANS, an averaging unit MITT and a threshold value switching unit SS. A data storage means DS is preferably provided too in order to buffer-store sample values AW of the sequence FA of sample values AW.

The transformation unit TRANS is coupled at the input end to the filter unit and/or to the data storage means DS. The input signal can be supplied to the transformation unit TRANS. The transformation unit TRANS is designed to transform the sequence FA of sample values AW into a sequence FT of transformation values TW. A profile of the sequence FT of transformation values TW is illustrated, by way of example, in FIG. 3B. The transformation comprises decimation of the sequence FA of sample values AW, so that a number of transformation values TW in the sequence FT of transformation values TW is lower than a number of sample values AW in the sequence FA of sample values AW. The transformation unit TRANS can therefore also be called the decimation unit.

The averaging unit MITT is coupled at the input end to an output of the transformation unit TRANS, at which output said averaging unit provides the sequence FT of transformation values TW. The averaging unit MITT is designed to form a sliding average value M as a function of the sequence FT of transformation values TW, for example as an arithmetic average of all the transformation values TW which lie within an averaging window of predefined width or with a predefined number of transformation values TW, with the averaging window being moved over the sequence FT of transformation values TW in predefined steps and the respectively determined arithmetic average being provided at the output end as the sliding average value M. However, it is also possible to determine the sliding average value M in another way, for example recursively by the current sliding average value M being determined as a function of a weighted, predetermined sliding average value M and a weighted, current transformation value TW. The averaging unit MITT can also be designed to determine a threshold value for recognizing the pulses IMP as a function of the sliding average value M, for example, by adjusting the threshold value as a function of a profile of the sliding average value M. However, the threshold value is preferably formed by the sliding average value M. Averaging is preferably performed in each case over so many successive transformation values TW that these transformation values together extend over at least one pulse IMP. As a result, the sliding average value M only follows signal changes which are slower than signal changes which are caused by the respective pulse IMP.

The threshold value switching unit SS is coupled at the input end to the filter unit, that is to say the low-pass filter unit TP, or to the data storage means DS. The sequence FA of sample values AW can thus be supplied to the threshold value switching unit SS. Furthermore, the threshold value switching unit SS is coupled at the input end to the averaging unit MITT. The threshold value, and in particular the sliding average value M, can thus be supplied to the threshold value switching unit SS. The threshold value switching unit SS is designed to recognize the pulses IMP as a function of the threshold value or the sliding average value M. For example, a pulse IMP is recognized when a sample value AW of the sequence FA of sample values AW is greater than the threshold value or the sliding average value M. However, provision can likewise be made to recognize a pulse IMP when a sample value AW of the sequence FA of sample values AW is lower than the threshold value or the sliding average value M. Furthermore, hysteresis can also be provided, so that a situation in which a first threshold value, which is predefined as a function of the sliding average value M, is exceeded is recognized and a situation in which a second threshold value, which is predefined as a function of the sliding average value M, is undershot is recognized. The threshold value switching unit SS is also designed to provide the recognized pulses IMP at the output end, for example in the form of a digital value one or zero as a function of whether a pulse IMP has been recognized or not. The threshold value switching unit SS is, for example, designed as a digital comparator which compares the respective digitally encoded sample value AW with the respective digitally encoded threshold value.

A divider unit T which is designed to reduce a frequency of the detected pulses IMP by a predefined division factor may be provided, for example, for the purpose of processing the recognized pulses IMP further. Furthermore, a pulse forming unit PULS can be provided in order to possibly suitably prepare the recognized pulses IMP for further units. Furthermore, a computation unit CPU can be provided, by means of which, for example, the predefined division factor can be predefined or by means of which, for example, adjustment of a parameter can be initiated, for example adjustment of a predefined magnitude value which is required for transforming the sequence FA of sample values AW into the sequence FT of transformation values TW. The computation unit CPU can also be provided to control the data storage means DS.

The device is preferably designed as a digital circuit and is preferably designed as an application-specific integrated circuit. The application-specific integrated circuit can also comprise the signal processing unit SIG and/or the analog/digital converter unit ADW and/or the low-pass filter unit TP and possibly also the divider unit T and/or the pulse forming unit PULS and/or the computation unit CPU and/or the sensor unit SENS and, in particular, the Hall element.

FIG. 2 shows, by way of example, the first profile of the sequence FA of sample values AW and of the associated sliding average value M. The numbers of sample values AW are plotted on the time axis of the graph; therefore a total of 1500 sample values AW are illustrated in the graph. The first profile shown in FIG. 2 can be produced, for example, by the vehicle, which is initially driven at an approximately constant speed, braking, for example using the eddy current brake. The braking reduces the speed of the vehicle and possibly also the rotation speed. The frequency of the pulses IMP also correspondingly reduces. Operation of the eddy current brake creates an increasing amplitude offset. However, the threshold value, that is to say the sliding average value M, is reliably tracked, so that it is possible to continue to reliably recognize the pulses IMP.

FIG. 3A shows the second profile of the sequence FA of sample values AW and FIG. 3B shows an associated profile of the sequence FT of transformation values TW. The transformation is performed in such a way that, starting from a predefined reference sample value REF, a difference DIFF between a subsequent sample value AW and the predefined reference sample value REF is determined. If the difference DIFF exceeds the predefined magnitude value MDIFF, this sample value AW is added as a transformation value TW to the sequence FT of transformation values TW. Furthermore, this sample value AW is predefined as the predefined reference sample value REF for the subsequent sample values AW. However, if the difference DIFF does not exceed the predefined magnitude value MDIFF, the difference DIFF between the subsequent sample value AW and the reference sample value REF is correspondingly determined and compared with the predefined magnitude value MDIFF. In FIG. 3A, those sample values AW whose difference DIFF is greater than the respectively predefined reference sample value REF are identified by a kink. In FIG. 3B, these sample values AW form the transformation values TW. Respectively successive transformation values TW are connected by a line to illustrate this more clearly.

The transformation can be influenced by the predefined magnitude value MDIFF as a parameter. Provision is preferably made to automatically determine the predefined magnitude value MDIFF. To this end, provision is preferably made to determine an amplitude AMP of at least one pulse IMP by determining a maximum value and a minimum value. The predefined magnitude value MDIFF is then preferably predefined by dividing the determined amplitude AMP by a predefined number of amplitude sections into which the determined amplitude is to be divided. The predefined magnitude value MDIFF can therefore be matched to the amplitude AMP of the pulses IMP in a very simple manner.

The transformation has the advantage that a pulse sequence with a substantially constant frequency is provided for determining the sliding average value M. The constant frequency is, in particular, substantially independent of the frequency of the pulses IMP in the input signal. As a result, the sliding average value M can be determined for a wide frequency range of pulses IMP in a precise and reliable manner. The threshold value for recognizing the pulses IMP can also be accordingly precise and reliable. The threshold value can therefore also be reliably tracked when the input signal is noisy and when the amplitude offset is large. The frequency range is, for example, approximately 1 Hz to 10 kHz. However, the frequency range can also be different.

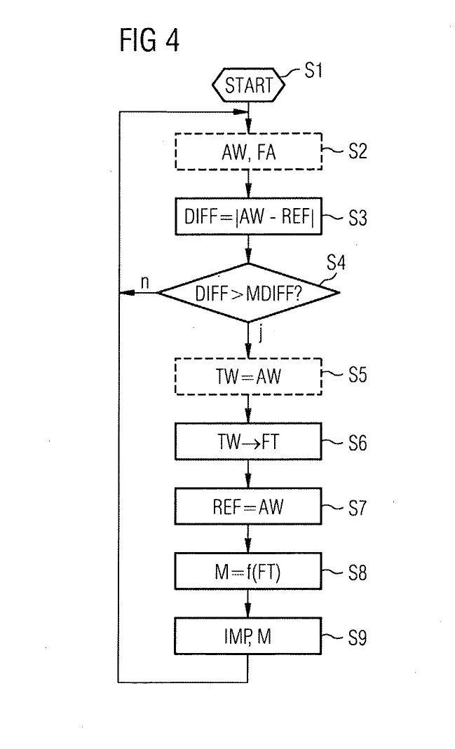

FIG. 4 shows a flowchart of a program for recognizing the pulses IMP. The program begins with step S1. In step S1, the predefined reference sample value REF is predefined, for example. The first sample value AW is predefined as a predefined reference sample value REF by way of example. However, the predefined reference sample value REF can also be predefined in a different way.

Step S2 can make provision for, at a predefined time interval, a sample value AW to be detected and the sequence FA of sample values AW to thus be generated, if this is not already available. In step S3, the difference DIFF is calculated as a value for the difference between the respectively current sample value AW and the predefined reference sample value REF. In step S4, a check is made as to whether the difference DIFF is greater than the predefined magnitude value MDIFF. If this condition is not satisfied, the program is continued in step S2 or step S3 with the next current sample value AW. However, if the condition is satisfied in step S4, the current sample value AW is selected as the next transformation value TW in step S5 and is added to the sequence FT of transformation values TW in step S6. However, provision may also be made for a value which is determined as a function of the current sample value AW to be added to the sequence FT of transformation values TW instead of current sample value AW. For example, provision may be made to multiply the current sample value AW by a predefined factor and/or to add or subtract an amplitude offset value before the value determined in this way is added as the transformation value TW to the sequence FT of transformation values. However, further or other modifications to the current sample value AW can be provided. The value, which is determined as a function of the current sample value AW and is added to the sequence FT of transformation values TW as a transformation value TW, then represents the current sample value AW.

In step S7, the current sample value AW is predefined as the predefined reference sample value REF for subsequent current sample value AW. In step S8, the sliding average value is determined as a function of the sequence FT of transformation values TW. Provision may also be made to determine the threshold value as a function of the determined sliding average value M. In step S9, a pulse IMP is recognized as a function of the sliding average value or the threshold value. The program is continued in step S2 or step S3 for the next current sample value AW.

What is claimed is:

1. A method for recognizing pulses in an input signal, comprising the steps:
transforming a sequence of sample values, which is formed as a function of the input signal or which is formed by the input signal, into a sequence of transformation values by in each case adding a transformation value, which represents a current sample value of the sequence of sample values, to the sequence of transformation values when this current sample value of the sequence of sample values deviates from a predefined reference sample value at least by a predefined magnitude value,
predefine the current sample value of the sequence of sample values, which deviates from the predefined reference sample value at least by the predefined magnitude value, as the predefined reference sample value for subsequent current sample values,
determining a sliding average value as a function of the sequence of transformation values, and
recognizing pulses in the input signal as a function of the sliding average value.

2. The method according to claim 1, wherein the current sample value of the sequence of sample values, which deviates from the predefined reference sample value at least by the predefined magnitude value, is added as the transformation value to the sequence of transformation values.

3. The method according to claim 1, wherein
an amplitude of at least one pulse is determined, and
the predefined magnitude value is predefined as a function of the determined amplitude of the at least one pulse and a predefined number of amplitude sections into which the determined amplitude of the at least one pulse is to be divided.

4. The method according to claim 1, wherein the input signal or a signal which is derived from this input signal is supplied to a threshold value switching unit, and the sliding average value is predefined to the threshold value switching unit as a threshold value or a threshold value which is determined as a function of the sliding average value.

5. A device for recognizing pulses in an input signal, the device being operable:
to transform a sequence of sample values, which is formed as a function of the input signal or which is formed by the input signal, into a sequence of transformation values by in each case adding a transformation value, which represents a current sample value of the sequence of sample values, to the sequence of transformation values when this current sample value of the sequence of sample values deviates from a predefined reference sample value at least by a predefined magnitude value,
to predefine the current sample value of the sequence of sample values, which deviates from the predefined reference sample value at least by the predefined magnitude value, as the predefined reference sample value for subsequent current sample values,
to determine a sliding average value as a function of the sequence of transformation values, and
to recognize pulses in the input signal as a function of the sliding average value.

6. The device according to claim 5, wherein the current sample value of the sequence of sample values, which deviates from the predefined reference sample value at least by the predefined magnitude value, is added as the transformation value to the sequence of transformation values.

7. The device according to claim 5, wherein
an amplitude of at least one pulse is determined, and
the predefined magnitude value is predefined as a function of the determined amplitude of the at least one pulse and a predefined number of amplitude sections into which the determined amplitude of the at least one pulse is to be divided.

8. The device according to claim 5, wherein the input signal or a signal which is derived from this input signal is supplied to a threshold value switching unit, and the sliding average value is predefined to the threshold value switching unit as a threshold value or a threshold value which is determined as a function of the sliding average value.

9. A device for recognizing pulses in an input signal, comprising:
means for transforming a sequence of sample values, which is formed as a function of the input signal or which is formed by the input signal, into a sequence of transformation values by in each case adding a transformation value, which represents a current sample value of the sequence of sample values, to the sequence of transformation values when this current sample value of the sequence of sample values deviates from a predefined reference sample value at least by a predefined magnitude value,
means to predefine the current sample value of the sequence of sample values, which deviates from the predefined reference sample value at least by the predefined magnitude value, as the predefined reference sample value for subsequent current sample values,
means for determining a sliding average value as a function of the sequence of transformation values, and
means for recognizing pulses in the input signal as a function of the sliding average value.

10. The device according to claim 9, comprising means for adding the current sample value of the sequence of sample values, which deviates from the predefined reference sample value at least by the predefined magnitude value, as the transformation value to the sequence of transformation values.

11. The device according to claim 9, further comprising:
means for determining an amplitude of at least one pulse, and
means for predefining the predefined magnitude value as a function of the determined amplitude of the at least one pulse and a predefined number of amplitude sections into which the determined amplitude of the at least one pulse is to be divided.

12. The device according to claim 9, further comprising means for supplying the input signal or a signal which is derived from this input signal to a threshold value switching unit, and means for predefining the sliding average value to the threshold value switching unit as a threshold value or a threshold value which is determined as a function of the sliding average value.
